(19) United States
(12) Patent Application Publication
(10) Pub. No.: US 2014/0225206 A1
(43) Pub. Date: Aug. 14, 2014

(54) PRESSURE LEVEL ADJUSTMENT IN A CAVITY OF A SEMICONDUCTOR DIE

(71) Applicants: Yizhen Lin, Cohoes, NY (US); Chad S. Dawson, Queen Creek, AZ (US); Hemant D. Desai, Gilbert, AZ (US); Lisa H. Karlin, Chandler, AZ (US); Keith L. Kraver, Gilbert, AZ (US); Mark E. Schlarmann, Chandler, AZ (US)

(72) Inventors: Yizhen Lin, Cohoes, NY (US); Chad S. Dawson, Queen Creek, AZ (US); Hemant D. Desai, Gilbert, AZ (US); Lisa H. Karlin, Chandler, AZ (US); Keith L. Kraver, Gilbert, AZ (US); Mark E. Schlarmann, Chandler, AZ (US)

(21) Appl. No.: 13/764,246

(22) Filed: Feb. 11, 2013

(51) Int. Cl. B81B 7/00; B81B 3/00

(52) U.S. Cl. CPC B81B 7/0032; B81B 3/0067
USPC 257/417; 438/51

(57) ABSTRACT

A semiconductor die (20) includes a substrate (30) and microelectronic devices (22, 26) located at a surface (32) of the substrate (30). A cap (34) is coupled to the substrate (30), and the microelectronic device (22) is positioned in the cavity (24). An outgassing material structure (36) is located within a cavity (24) between the cap (34) and the substrate (30). The outgassing material structure (36) releases trapped gas (37) to increase the pressure within the cavity (24) from an initial pressure level (96) to a second pressure level (94). The cap (34) may include another cavity (28) containing another microelectronic device (26). A getter material (42) may be located within the cavity (28). The getter material (42) is activated to absorb residual gas (46) in the cavity (28) and decrease the pressure within the cavity (28) from the initial pressure level (96) to a third pressure level (92).

### TECHNICAL FIELD OF THE INVENTION

The present invention relates generally to microelectronic devices. More specifically, the present invention relates to adjusting a pressure level of a hermetically sealed cavity in a semiconductor die in which a microelectronic device is located.

### BACKGROUND OF THE INVENTION

Advancements in micromachining and other microfabrication techniques and processes have enabled manufacture of a wide variety of microelectronic and microelectromechanical systems (MEMS) devices. One common application of MEMS is the design and manufacture of sensor devices. MEMS sensor devices are widely used in applications such as automotive, inertial guidance systems, household appliances, game devices, protection systems for a variety of devices, and many other industrial, scientific, and engineering systems.

### BRIEF DESCRIPTION OF THE DRAWINGS

A more complete understanding of the present invention may be derived by referring to the detailed description and claims when considered in connection with the Figures, wherein like reference numbers refer to similar items throughout the Figures, and:

FIG. 1 shows a cross-sectional side view of a semiconductor die in accordance with an embodiment;

FIG. 2 shows a cross-sectional side view of a semiconductor die in accordance with another embodiment;

FIG. 3 shows a cross-sectional side view of a semiconductor die in accordance with another embodiment;

FIG. 4 shows an inner surface of a cap of the semiconductor die of FIG. 3;

FIG. 5 shows a cross-sectional side view of a semiconductor die in accordance with another embodiment;

FIG. 6 shows a table of an increase in pressure within a sealed chamber as a function of temperature for a number of outgassing material structures;

FIG. 7 shows a table of pressure levels in a pair of cavities of the semiconductor die of FIG. 2 relative to an initial pressure level; and

FIG. 8 shows a flowchart of a fabrication process for fabricating the semiconductor die in accordance with yet another embodiment.

### DETAILED DESCRIPTION

Various semiconductor dies include a sealed cap that covers the microelectronic devices and seals them from moisture and foreign materials that could have deleterious effects on device operation. Additionally, some devices have particular pressure requirements in which they most effectively operate. Thus, the cap can include a cavity in which these devices are located, where the cavity has a particular cavity pressure suitable for effective operation of these devices.

Various microelectronic devices, such as some microelectromechanical systems (MEMS) devices, optoelectronic/photonic devices, integrated circuits, and the like, need to be packaged in a vacuum atmosphere in order to operate correctly. Other types of microelectronic devices operate in a non-vacuum environment in order to avoid an underdamped response in which movable elements of the device can undergo multiple oscillations in response to a single disturbance. By way of example, angular rate sensors, also referred to as gyroscopes, may require a vacuum atmosphere in order to achieve a high quality factor, Q, for low voltage operation and high signal response. Conversely, an accelerometer may require operation in a damped mode in order to reduce shock and vibration sensitivity. Therefore, the two types of sensors may have different pressure requirements for the cavities in which they are located.

Multiple sensors may be integrated into a single device package. In such a multiple sensor device package, a single semiconductor die may contain, for example, both accelerometer and angular rate sensors. A semiconductor die having multiple co-located sensors can reduce both cost and form factor. However, differing cavity pressure requirements have not generally been compatible with prior packaging technologies.

Embodiments entail semiconductor dies containing one or more hermetically sealed cavities in which microelectronic devices are located. Embodiments further entail methodology for adjusting pressure levels in the one or more cavities using an outgassing material structure. The outgassing material structure releases gas molecules during a wafer bonding process to effectively increase the pressure levels in the one or more cavities. Additionally, a getter material may be used in other cavities. The getter material is activated during the wafer bonding process and combines with gas molecules to effectively decrease the pressure level in these other cavities. Accordingly, semiconductor dies can be fabricated having multiple cavities with differing pressure level requirements.

FIG. 1 shows a cross-sectional side view of a semiconductor die 20 in accordance with an embodiment. In an embodiment, semiconductor die 20 is a microelectromechanical systems (MEMS) die containing at least two MEMS devices housed in hermetically sealed cavities, each having a different cavity pressure requirement. In the illustrated embodiment, semiconductor die 20 includes a first MEMS device, referred to herein as an accelerometer 22, positioned in a cavity, referred to herein as an accelerometer cavity 24. Additionally, semiconductor die 20 includes a second MEMS device, referred to herein as an angular rate sensor 26, positioned in another cavity, referred to herein as a rate sensor cavity 28.

In some embodiments, the design of angular rate sensor 26 calls for low pressure operation, e.g., at approximately vacuum, to achieve a high quality factor, Q. Conversely, the design of accelerometer 22 calls for a pressure level closer to atmospheric pressure, i.e., greater than vacuum, in order to avoid an underdamped response. Structure and methodology described herein yield a configuration in which the pressure level in first cavity 24 differs from the pressure level in second cavity 28.

For clarity and ease of description, only a single accelerometer 22 and a single angular rate sensor 26 are shown. However, it should be understood that alternative embodiments can include different microelectronic devices having different cavity pressure requirements that are co-located on a single substrate. These microelectronic devices may be in the form of integrated circuits, optoelectronic/photonic devices, and a variety of MEMS devices, such as magnetic sensors, gas sensors, actuators, switches, and so forth having one or more movable elements or masses. Additionally, or alternatively, either of cavities 24 and 28 may have more than one microelectronic device located therein, each having similar pressure level requirements.

Semiconductor die 20 includes a silicon-based substrate 30 having a surface 32 at which accelerometer 22 and angular rate sensor 26 are located. A cap 34 is coupled to surface 32 of substrate 30. Cap 34 has accelerometer and rate sensor cavities 24 and 28, respectively, formed therein. In accordance with an embodiment, cap 34 is bonded or otherwise coupled to surface 32 of substrate 30 such that each of cavities 24 and 28 is hermetically sealed and isolated from one another. That is, each of accelerometer and rate sensor cavities 24 and 28 is suitably sealed to largely prevent entry of water vapor and/or foreign bodies so as to maintain the proper functioning and reliability of accelerometer 22 and angular rate sensor 26. Although cap 34 is shown having cavities 24 and 28 formed therein, it should be understood that cavities 24 and 28 are located between cap 34 and substrate 30. As such, in alternative embodiments cavities 24 and 28 may be formed in substrate 30 in lieu of being formed in cap 34.

It will be appreciated that accelerometer 22 and angular rate sensor 26 can include one or more movable elements suspended above substrate 30 by, for example, suspension springs (not shown). Additionally, accelerometer 22 and angular rate sensor 26 may additionally include one or more non-illustrated fixed and moving electrodes. Indeed, the specific structure and configuration of accelerometer 22 and angular rate sensor 26 may vary. However, a description of the specific structure and configuration of accelerometer 22 and angular rate sensor 26 is not needed to enable or fully describe the present embodiment, and are thus not described in further detail.

In the embodiment of FIG. 1, an outgassing material structure 36 is located on an inner surface 38 of cap 34 within first cavity 24, but outgassing material structure 36 is absent from rate sensor cavity 28. Outgassing material structure 36 may be any suitable material having gas 37 (represented by a dotted circle with an outwardly directed dotted arrow) that is dissolved, trapped, frozen, or absorbed into it. Outgassing material structure 36 thus outgases, i.e., loses or releases, this trapped gas 37 over a period of time. Typically, outgassing of certain materials presents challenges to creating and maintaining clean high-vacuum environments. Indeed, some outgassing material structures may release enough light-weight gaseous molecules (such as, hydrogen, carbon monoxide, methane) to interfere with industrial vacuum processes. Therefore, design considerations typically call for certain materials and methods of manufacture and preparation to significantly reduce the level of outgassing.

Embodiments described herein entail the express formation of outgassing material structure 36 on inner surface 38 of cap 34 within first cavity 24. It should be appreciated, however, that outgassing structure may be accessible to cavity 24 by, for example, being deposited or otherwise located on surface 32 of substrate 30 within cavity 24. Outgassing material structure 36 releases, i.e., outgases, gas molecules 37 for the purpose of increasing a pressure level within accelerometer cavity 24. In one embodiment, outgassing material structure 36 is tetraethyl orthosilicate (TEOS). However, other exemplary outgassing material structures can include, for example, silicon oxynitride (SiON), phosphosilicate glass (PSG), undoped silicate glass (USG), high density polyethylene (HDP), and the like, or some combination thereof. As discussed below in connection with methodology for fabricating semiconductor die 20, a suitable volume of outgassing material structure 36 is deposited on inner surface 38 of cap 34. Outgassing material structure 36 releases gas 37 toward the end of a wafer bonding process in which cap 34 is coupled to surface 32 of substrate 30 or after cap 34 is coupled to surface 32 in order to increase the pressure level within accelerometer cavity 24.

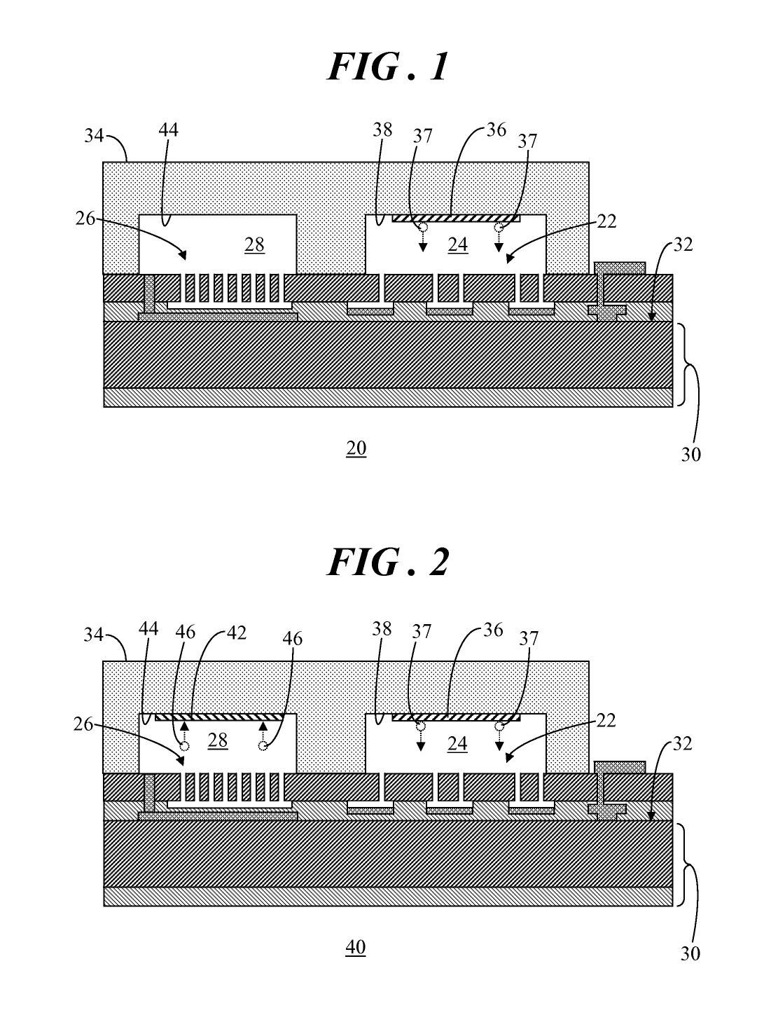

FIG. 2 shows a cross-sectional side view of a semiconductor die 40 in accordance with another embodiment. Like semiconductor die 20 (FIG. 1), semiconductor die 40 also includes accelerometer 22 and angular rate sensor 26 located at surface 32 of substrate 30. Again, cap 34 is coupled to surface 32 of substrate 30 with accelerometer 22 being located within accelerometer cavity 24 and angular rate sensor 26 being located within rate sensor cavity 28. Outgassing material structure 36 is deposited on inner surface 38 of accelerometer cavity 24, and is absent in rate sensor cavity 28.

In accordance with the embodiment of FIG. 2, a getter material 42 is located within rate sensor cavity 28. More particularly, getter material 42 may be deposited on an inner surface 44 of cap 34 within rate sensor cavity 28. Getter material 42 is a reactive material that can be placed inside a vacuum environment for the purpose of completing and maintaining the vacuum. An exemplary getter material 42 may be a zirconium based alloy that can chemically take up, i.e., absorb, active gas species including water, carbon monoxide, carbon dioxide, molecular oxygen, molecular nitrogen, molecular hydrogen, and so forth. Alternatively, another suitable getter material may be used. When gas molecules 46 (represented by a dotted circle with an inwardly directed dotted arrow) present within rate sensor cavity 28 strike getter material 42, gas molecules 46 combine with getter material 42 chemically or by adsorption. Thus, getter material 42 can remove small amounts of residual gas from the evacuated space of rate sensor cavity 28 in order to decrease the pressure level within rate sensor cavity 28.

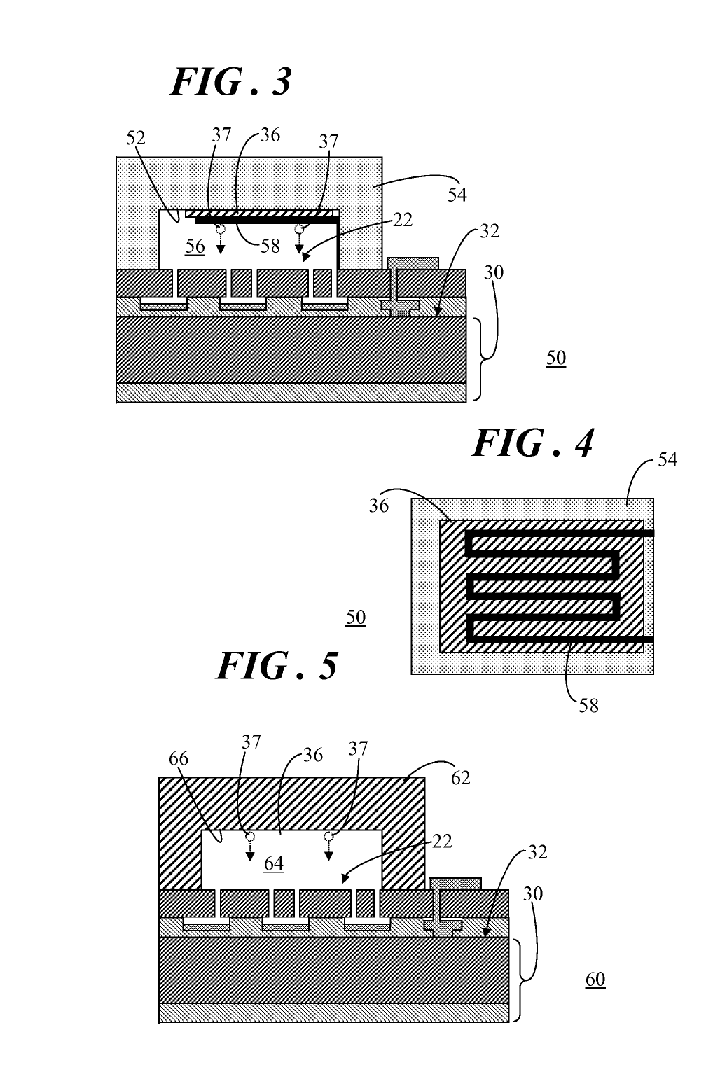

Referring to FIGS. 3 and 4, FIG. 3 shows a cross-sectional side view of a semiconductor die 50 in accordance with another embodiment, and FIG. 4 shows an inner surface 52 of a cap 54 of semiconductor die 50. Semiconductor die 50 is a single cavity MEMS die having accelerometer 22 located at surface 32 of substrate 30, and cap 54 has an accelerometer cavity 56 formed therein. Cap 54 is coupled to surface 32 with accelerometer 22 positioned in accelerometer cavity 56. Some designs may not call for the multiple cavity configurations shown in FIGS. 1 and 2. Instead, the design of semiconductor die 50 may call for a single cavity 56 with a subsequent increase in pressure level occurring during or after cap 54 is coupled to substrate 30. Thus, outgassing material structure 36 may be deposited onto inner surface 52 of cap 54.

In accordance with a further embodiment, a heater element 58 may be located in cavity 56. In the illustrated embodiment, heater element 58 is a serpentine arrangement of conductive material, such as polysilicon, deposited on outgassing material structure 36. Heater element 58 may be activated after cap 54 is bonded to substrate 30 in order to achieve a higher rate of thermal processing. The rate (speed) of outgassing increases at higher temperatures because the vapor pressure and rate of chemical reaction increases. Accordingly, the rapid thermal processing of outgassing material structure 36 can further facilitate outgassing in order to achieve a desired increase in the pressure level of cavity 56. Heater element 58 may subsequently be deactivated after outgassing material structure 36 has sufficiently outgassed.

Heater element 58 is shown in the single cavity configuration of semiconductor die 50 for illustrative purposes. It should be understood that heater element 58 may be implemented with semiconductor die 20 (FIG. 1) and/or in either cavity 24 and 28 within semiconductor die 40 (FIG. 2) and/or with a semiconductor die design shown in FIG. 5 (discussed below). Additionally, while heater element 58 is activated, a heat sink (not shown) may at least temporarily be placed on the outer surface of cap 54 in order to conduct heat through outgassing material structure 36 and cap 54, and away from accelerometer 22.

FIG. 5 shows a cross-sectional side view of a semiconductor die 60 in accordance with another embodiment. The previously described embodiments show semiconductor dies having caps formed of, for example, silicon, with outgassing material structure 36 (FIG. 1) and additionally getter material 42 (FIG. 2) located on respective inner surfaces of the cap. Semiconductor die 60 includes accelerometer sensor 22 located at surface 32 of substrate 30, and a cap 62 coupled to substrate 30 and having a cavity 64 formed therein. Accelerometer sensor 22 is positioned in cavity 64. In this design, cap 62 is formed from outgassing material structure 36, such as tetraethyl orthosilicate (TEOS). As such, deposition of outgassing material structure 36 on an inner surface 66 of cap 62 is not called for. Instead, the exposed inner surface 66 of cap 62 is located within cavity 64 and thus releases gas molecules 37 into cavity 64 in order to increase the pressure level within cavity 64.

Cap 62, formed from outgassing material structure 36, is shown in the single cavity configuration of semiconductor die 60. However, a cap formed from outgassing material structure 36 may be adapted for implementation within the dual cavity configurations of semiconductor dies 20 and 40, shown in FIGS. 1 and 2. In order to do so, inner surface 44 of cap 34 in either of semiconductor dies 20 and 40 may have a coating of material that is substantially impervious to outgassing material structure 36 so that outgassing material structure 36 is largely prevented from releasing gas molecules 37 into cavity 28.

FIG. 6 shows a table 70 of an increase in pressure levels 72 within a sealed chamber as a function of temperature 74 for a number of outgassing material structures. Pressure levels 72 due to outgassing of tetraethyl orthosilicate (TEOS) material 36 is represented by a solid line. Pressure levels 72 due to outgassing of a silicon oxynitride (SiON) material 76 is represented by a dashed line. Pressure levels 72 due to outgassing of a phosphosilicate glass (PSG) material 78 is represented by a dotted line. Pressure levels 72 due to outgassing of an undoped silicate glass (USG) material 80 is represented a dash-dot line, and pressure levels 72 due to outgassing of a high density polyethylene (HDP) 82 is represented by a dash-dot-dot line.

With reference to the outgassing of TEOS outgassing material structure 36 in table 70, TEOS outgassing material structure 36 of a known volume is placed in a chamber of known volume. For each test iteration, TEOS outgassing material structure 36 is heated to a particular temperature for a predetermined duration, and pressure level 72 of the chamber is measured following the heating duration. With the duration of heat exposure held constant for each test iteration, table 70 reveals that pressure level 72 within the sealed chamber rises commensurately with the rise in temperature 74. For example, at a temperature of approximately one hundred degrees Celsius, the pressure in the chamber is at a first pressure level 84 and at a temperature of approximately five hundred degrees Celsius, the pressure in the chamber is at a second pressure level 86. Accordingly, experimental results reveal that TEOS outgassing material structure 36 can achieve a fivefold increase in pressure level 72 within a sealed chamber when TEOS outgassing material structure 36 is heated.

Since the exposure duration is being held constant for each test iteration, table 70 also generally reveals that as TEOS outgassing material structure 36 is heated the rate of outgassing also increases. Again, the rate (speed) of outgassing increases at higher temperatures because the vapor pressure and rate of chemical reaction increases.

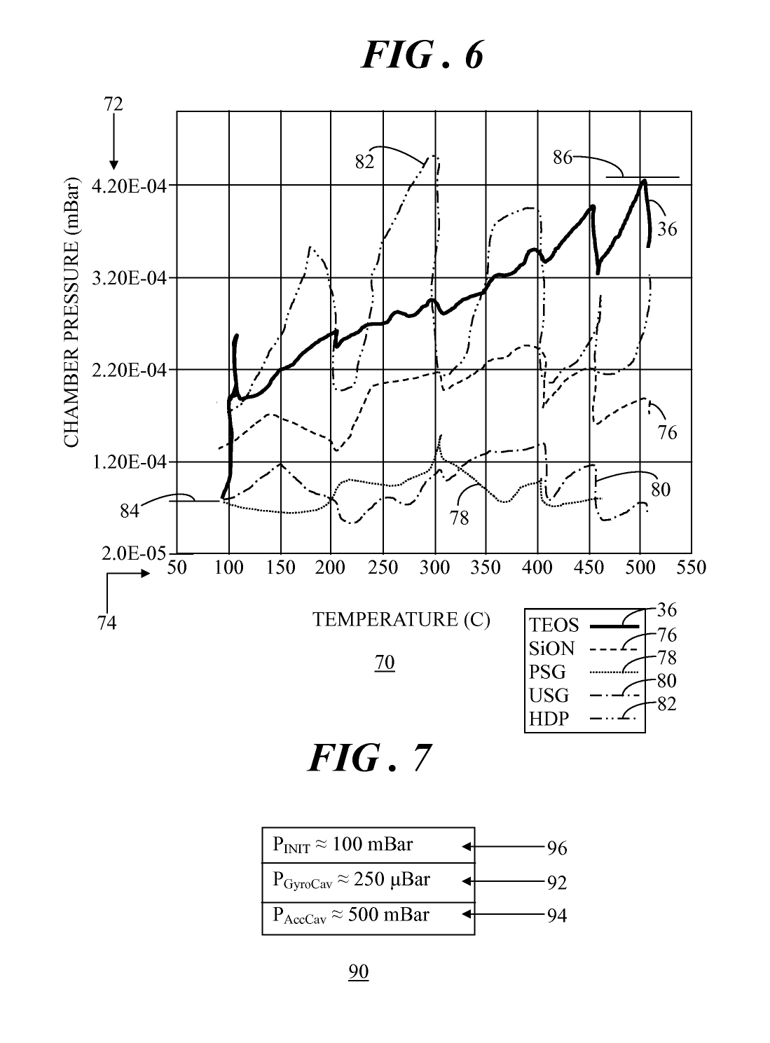

Referring to FIG. 2 and FIG. 7, FIG. 7 shows a table 90 of pressure levels 92 and 94 in a pair of cavities 24 and 28 of semiconductor die 40 relative to an initial pressure level 96. As shown in FIG. 2, accelerometer 22 and angular rate sensor 26 are laterally displaced away from one another and are located side by side on substrate 30. However, accelerometer 22 and angular rate sensor 26 are hermetically isolated from one another by their respective cavities 24 and 28. In rate sensor cavity 28, getter material 42 is deposited. After thermal activation, getter material 42 is able to chemically absorb reactive gaseous molecules 46.

In an illustrative scenario, the cavity pressure in each of cavities 24 and 28, i.e., initial pressure level 96 (labeled P_{INIT}), may be pumped down to a residual partial pressure of approximately one hundred millibars during bonding. Semiconductor die 40 is typically subjected to heat during bonding of cap 34 to substrate 30. By way of example, eutectic wafer level bonding can impose a peak temperature of approximately four hundred degrees Celsius. At this temperature, getter material 42 is activated so that getter material 42 absorbs at least a portion of residual gaseous molecules 46 present in rate sensor cavity 28. Thus, following absorption of at least a portion of residual gaseous molecules 46, pressure level 92 (labeled P_{GyroCav}) within rate sensor cavity 28 may decrease from initial pressure level 96 to, for example, approximately two hundred fifty microbars. However, following release of gaseous molecules 37 from outgassing material structure 36, pressure level 94 (labeled P_{AccCav}) within accelerometer cavity 24 may increase from initial pressure level 96 to, for example, approximately five hundred millibars. This condition represents a potential pressure difference ratio between cavities 28 and 24 of approximately 1:2000. As such, pressure level 94 for accelerometer cavity 24 may be produced at around the two hundred sixty millibar range after cool down of semiconductor die 40.

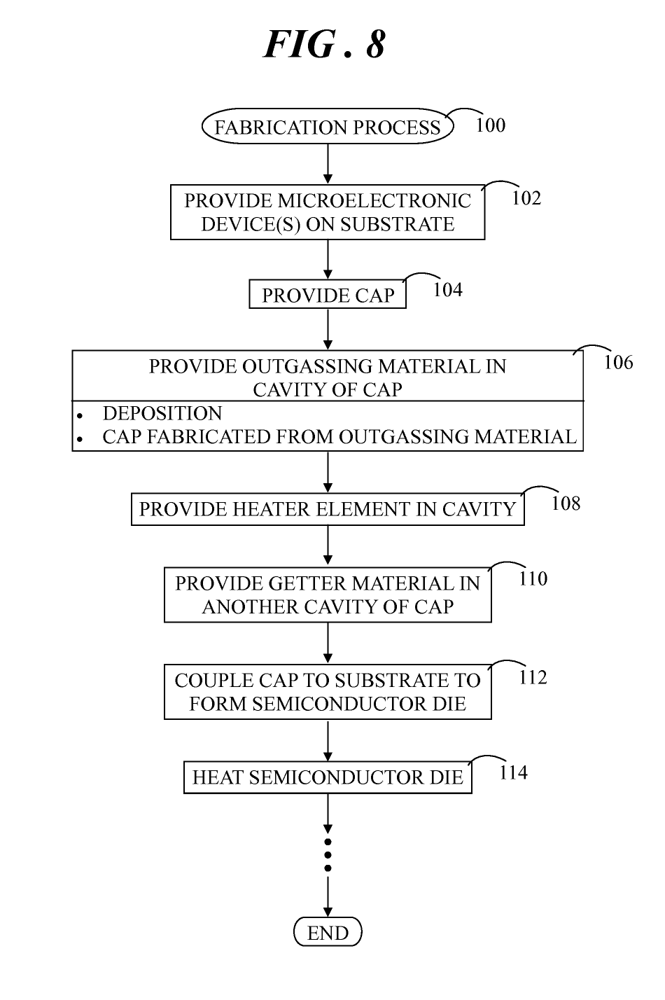

FIG. 8 shows a flowchart of a fabrication process 100 for fabricating a semiconductor die in accordance with yet another embodiment. Fabrication process 100 is executed to produce dies having microelectronic devices housed within cavities designed to operate most effectively at certain predetermined cavity pressures. For convenience, fabrication process 100 is described using a particular order of operations. However, portions of fabrication process 100 may be performed in a different order or using different types of operations than what is described below.

For clarity and ease of explanation, the operations of fabrication process 100 are described in connection with the fabrication of semiconductor die 40 (FIG. 2). As such reference should be made to FIG. 2 in connection with the operations of fabrication process 100. However, it should be appreciated that fabrication process 100 may be readily implemented to fabricate any of semiconductor dies 20 (FIG. 1), 50 (FIG. 3), or 60 (FIG. 4), or any other semiconductor die having one or more hermetically sealed cavities for which a particular cavity pressure is desired. Additionally, fabrication process 100 is described in connection with the fabrication of a single semiconductor die 40. However, in practice, fabrication process 100 may be implemented during wafer level processing to concurrently fabricate a multiplicity of semiconductor dies 40.

Fabrication process 100 may begin with an operation 102. Operation 102 entails providing the microelectronic devices. More particularly, substrate 30 is provided with accelerometer 22 and angular rate sensor 26 formed thereon. The process steps used to form accelerometer 22 and angular rate sensor 26 are not described herein, as accelerometer 22 and angular rate sensor 26 can be formed using any of a number of known or upcoming fabrication processes.

In addition to task 102, an operation 104 is performed. Operation 104 entails providing cap 34. Cap 34 may be formed from, for example, crystalline silicon, and is manufactured to include accelerometer cavity 24 and rate sensor cavity 28. The process steps used to form cap 34 are not described herein, as cap 34 can be formed using any of a number of known or upcoming fabrication techniques. It should be understood that in some embodiments, the cap may not have separately formed cavities 24 and 28. Instead, accelerometer 22 and angular rate sensor 26 may be formed in cavities within the device die, i.e., within substrate 30.

Fabrication process 100 continues with an operation 106. At operation 106, outgassing material structure 36 is provided in accelerometer cavity 24 of cap 34. Alternatively, at operation 106, outgassing material structure 36 may be provided on surface 32 of substrate 30 within accelerometer cavity 24. Outgassing material structure 36 may be deposited using, for example, a low pressure chemical vapor deposition (LPCVD) technique to produce a relatively thin film of outgassing material structure 36 (e.g., TEOS) on inner surface 38 of cap 34 within accelerometer cavity 24. The deposited outgassing material structure 36 should be thick enough to hold a sufficient volume of gaseous molecules 37 for release into accelerometer cavity 24. Both extent and thickness of outgassing material structure 36 can be determined according to the total amount of gas 37 that is to be released into accelerometer cavity 24 to effectively increase the pressure level within accelerometer cavity 24. Alternatively, cap 34 may be formed from a suitable outgassing material structure 36, as discussed in connection with semiconductor die 60 of FIG. 5. Thus, at operation 106, outgassing material structure 36 is provided in accelerometer cavity 64 (FIG. 5) since cap 34 is manufactured from outgassing material structure 36.

An operation 108 may optionally be performed following operation 106. At operation 106, heater element 58 (FIG. 3) may be provided in accelerometer cavity 64, as discussed in connection with semiconductor die 50 shown in FIGS. 3 and 4. As such, a suitable material layer, such as polysilicon, may be deposited over outgassing material structure 36, and subsequently patterned and etched, to form the serpentine configuration of heater element 58.

Fabrication process 100 continues with an operation 110. At operation 110, getter material 42 is deposited on inner surface 44 of cap 34 within rate sensor cavity 28 and/or on the device die, i.e., surface 32 of substrate 30. Getter material 42 may be a thin-film getter material sputtered or deposited at a desired location on inner surface 44 of cap 34 within rate sensor cavity 28. Getter material 42 should be thick enough to have sufficient sorption capacity, as apparent to one skilled in the art. Both extent and thickness of getter material 42 can be determined according to the total amount of gas 46 that is expected to be residing in rate sensor cavity 28. Various getter materials 42 may be employed depending upon the nature of the residual gases present in rate sensor cavity 28 and/or the nature of any gases that may be released from the sidewalls of cap 34 and/or from any other structures located within rate sensor cavity 28. Of course, it should be readily apparent that for some semiconductor die configurations getter material 42 is not used, for example, semiconductor dies 20 (FIG. 1), 50 (FIG. 3), and 60 (FIG. 5). Accordingly, when getter material 42 is not used, operation 110 would not be performed.

Following operation 110 or following operation 108 when getter material 42 is not used, fabrication process 100 continues with a task 112. At task 112, cap 34 is coupled to substrate 30 with accelerometer 22 positioned in accelerometer cavity 24 and angular rate sensor 26 positioned in rate sensor cavity 28. The coupling of cap 34 to substrate 30 may occur in a vacuum environment so that initial pressure 96 (FIG. 7) in each of accelerometer and rate sensor cavities 24 and 28 is near vacuum, i.e., significantly below one atmosphere.

An operation 114 is performed in connection with operation 112. At operation 114, semiconductor die 40 is heated. In an exemplary execution of operations 112 and 114, a eutectic bonding process may be performed to hermetically seal cap 34 onto substrate 30. The peak bond temperatures for eutectic bonding are typically set in the range of, for example, three hundred eighty to four hundred degrees Celsius. This temperature is sufficient to activate getter material 42 so that getter material 42 absorbs at least a portion of gaseous molecules 46 present in rate sensor cavity 28 in order to reduce a pressure level within rate sensor cavity 28 from initial pressure level 96 (FIG. 7) to pressure level 92 (FIG. 7). Additionally, the peak bond temperature of around four hundred degrees Celsius facilitates the rapid release of gas molecules 37 from outgassing material structure 36 into accelerometer cavity 24 in order to increase a pressure level within accelerometer cavity from initial pressure level 96 to pressure level 94 (FIG. 7).

In some embodiments, eutectic bonding may not be performed and/or peak temperature of four hundred degrees Celsius may not be sufficient to obtain the desired rate of outgassing into accelerometer cavity 24 and or to may not be sufficient to totally absorb the residual gas 46 in rate sensor cavity 28. Therefore, a post coupling operation may be performed at operation 114 to thereby activate getter material 42 and/or to increase the rate of release of gas from outgassing material structure 36. For example, heater element 58 (FIG. 3) may be activated to provide rapid thermal processing of outgassing material structure 36.

Following operation 114, fabrication process 100 may continue with additional processing operations, such as wafer level testing, packaging, burn-in, dicing, and so forth as known to those skilled in the art. Eventually, fabrication process 100 ends following the fabrication of semiconductor dies having microelectronic devices housed within cavities designed to operate most effectively at certain predetermined cavity pressures.

In summary, embodiments of the invention entail semiconductor dies having caps bonded thereto, where the caps have one or more formed therein. At least one microelectronic device is positioned in each cavity. Methodology entails adjusting pressure levels in the one or more cavities using an outgassing material structure. In particular, an outgassing material structure is provided in a cavity in each semiconductor die. The outgassing material structure is configured to release gas trapped in the outgassing material structure into the hermetically sealed cavity and thereby increase a pressure in the cavity. A getter material may be provided in another cavity in each semiconductor die. The getter material is configured to absorb residual gas present in the other cavity and thereby decrease a pressure level in the other cavity. As such, semiconductor dies can be efficiently and cost effectively fabricated having multiple cavities with differing pressure level requirements.

Although the preferred embodiments of the invention have been illustrated and described in detail, it will be readily apparent to those skilled in the art that various modifications may be made therein without departing from the spirit of the invention or from the scope of the appended claims. That is, it should be appreciated that the exemplary embodiments are only examples, and are not intended to limit the scope, applicability, or configuration of the invention.

What is claimed is:

1. A semiconductor die comprising:
a substrate;
a microelectronic device located at a surface of said substrate;
a cap coupled to said surface of said substrate with said microelectronic device positioned in a cavity located between said cap and said substrate; and
an outgassing material structure located within said cavity, wherein said outgassing material structure released gas trapped in said outgassing material structure into said cavity and thereby increased a pressure in said cavity from a first pressure level to a second pressure level.

2. A semiconductor die as claimed in claim 1 wherein said cavity is formed in said cap.

3. A semiconductor die as claimed in claim 1 wherein said outgassing material structure is located on an inner surface of said cap within said cavity.

4. A semiconductor die as claimed in claim 1 wherein said cap is formed from an outgassing material, and an exposed surface of said cap located within said cavity is said outgassing material structure.

5. A semiconductor die as claimed in claim 1 wherein said outgassing material structure includes tetraethyl orthosilicate (TEOS).

6. A semiconductor die as claimed in claim 1 wherein said microelectronic device is a first microelectronic device, said cavity is a first cavity, and said semiconductor die further comprises a second microelectronic device located at said surface of said substrate and laterally displaced away from said first microelectronic device, said second microelectronic device being positioned in a second cavity located between said cap and said surface of said substrate, and said outgassing material structure is absent from said second cavity.

7. A semiconductor die as claimed in claim 6 wherein:
said first microelectronic device includes a microelectromechanical systems (MEMS) accelerometer; and
said second microelectronic device includes a MEMS angular rate sensor.

8. A semiconductor die as claimed in claim 6 further comprising a getter material located within said second cavity.

9. A semiconductor die as claimed in claim 8 wherein said getter material is deposited on an inner surface of said cap within said second cavity.

10. A semiconductor die as claimed in claim 6 wherein a third pressure level in said second cavity is lower than said second pressure level in said first cavity.

11. A semiconductor die as claimed in claim 10 further comprising a getter material located within said second cavity, wherein said semiconductor die has been heated from a first temperature to a second temperature so that said getter material has absorbed residual gas present in said second cavity and decreased said pressure in said second cavity to said third pressure level, said third pressure level being less than said first pressure level.

12. A semiconductor die as claimed in claim 1 further comprising a heater element located in said cavity, said heater element being positioned for heating said outgassing material structure to increase said pressure in said cavity from said first pressure level to said second pressure level.

13. A method of fabricating a semiconductor die that includes a microelectronic device formed on a substrate and a cap defining a cavity, said method comprising:
providing an outgassing material structure accessible within said cavity; and
coupling said cap to a surface of said substrate with said microelectronic device positioned in said cavity, said outgassing material structure releasing gas trapped in said outgassing material structure to increase a pressure in said cavity from a first pressure level to a second pressure level.

14. A method as claimed in claim 13 further comprising heating said semiconductor die from a first temperature to a second temperature to increase said pressure in said cavity from said first pressure level to said second pressure level.

15. A method as claimed in claim 13 wherein said microelectronic device is a first microelectronic device, said cavity is a first cavity, a second microelectronic device is formed on said substrate, said second microelectronic device being laterally displaced away from said first microelectronic device, said cap and said surface define a second cavity, and said method further comprises:
providing a getter material in said second cavity, said getter material having an activation temperature;
said coupling operation couples said cap to said surface of said substrate with said second microelectronic device positioned in said second cavity, said pressure in each of said first and second cavities being at said first pressure level in response to said coupling operation; and
heating said semiconductor die from a first temperature to said activation temperature to increase said pressure in said first cavity, and wherein said heating operation activates said getter material so that said getter material absorbs residual gas present in said second cavity to decrease said pressure in said second cavity to a third pressure level, said third pressure level being less than said first pressure level.

16. A method as claimed in claim 15 further comprising performing said coupling operation in a vacuum environment such that said first pressure level in each of said first and second cavities is less than standard atmospheric pressure.

17. A method as claimed in claim 13 further comprising:
providing a heater element within said cavity; and
following said coupling operation, activating said heater element to increase a temperature of said outgassing material structure from a first temperature to a second temperature to increase said pressure in said cavity.

18. A semiconductor die comprising:
a substrate having a surface;
a first microelectronic device located at said surface of said substrate;
a second microelectronic device located at said surface of said substrate and laterally displaced away from said first microelectronic device;
a cap coupled to said surface of said substrate with said first microelectronic device positioned in a first cavity defined by said cap and said substrate, and said second microelectronic device positioned in a second cavity defined by said cap and said substrate; and
an outgassing material structure located on an inner surface within said first cavity, said outgassing material structure being absent from said second cavity, wherein said outgassing material structure released gas trapped in said outgassing material structure such that a first pressure level in said first cavity is greater than a second pressure level in said second cavity.

19. A semiconductor die as claimed in claim 18 further comprising a getter material located within said second cavity, wherein said getter material absorbed residual gas from said second cavity such that said pressure in said second cavity has been decreased from an initial pressure level to said second pressure level.

20. A semiconductor die as claimed in claim 18 further comprising a heater element located in said cavity, said heater element having been activated after said cap is coupled to said substrate to increase said pressure in said cavity.
